(19) United States
(12) Patent Application Publication
(10) Pub. No.: US 2026/0266870 A1
(43) Pub. Date: Sep. 10, 2026

(54) ELECTRONIC DEVICE TESTER

(71) Applicant: Communications Test Design, Inc., West Chester, PA (US)

(72) Inventor: Drice BAHAJAK, West Chester, PA (US)

(73) Assignee: Communications Test Design, Inc., West Chester, PA (US)

(21) Appl. No.: 19/073,759

(22) Filed: Mar. 7, 2025

(51) Int. Cl. G01R 1/04; G01R 1/02; H04R 29/00; H04W 24/08

(52) U.S. Cl. CPC G01R 1/0416; G01R 1/025; H04R 29/001; H04R 29/004; H04W 24/08

(57) ABSTRACT

An electronic device tester is shown and described. The electronic device tester includes a housing created by a plurality of supports. The housing has an interior volume. A door secured to the plurality of supports granting access to the interior volume. Sound dampening materials cover at least part of the interior volume. At least one speaker is located within the interior volume. At least one microphone is located within the interior volume.

### BACKGROUND OF THE INVENTION

Technology is always advancing and has done so at a rapid pace for the last several decades. Technology has become sophisticated, smaller, and accessible across the globe. This has led to technology becoming integral in everyday life. As with any integral element of life, the demand is high. This high demand has led to a rise in the cost of technological devices.

In addition to high demand, the simple replacement of devices can be expensive. If one merely discards older equipment or equipment with minor defects for a brand-new piece the cost can escalate quickly. If, however, technology is upgraded, or repaired this process can be much more cost effective for both the company and consumer.

It has become routine for companies to resell used products. In some instances products can simply be resold as is. However, this may not allow a company to charge the maximum amount for a used product. In order to guarantee a product is functional and thus charge a higher amount for used products a company needs to test functionality of the devices. Testing a device by hand can be time consuming and inaccurate.

Many companies have been taking advantage of the repair instead of discard philosophy. Further, many consumers are happy purchasing a lightly used and repaired device instead of a brand new one. However, these processes come with new challenges in order to remain effective. Consequently, there is always a need for an improvement in the art.

### SUMMARY OF THE INVENTION

The present invention provides an electronic device tester wherein the same can be utilized for providing convenience for the user when testing electronic devices for functionality. The electronic device tester includes a housing created by a plurality of supports. The housing has an interior volume. A door secured to the plurality of supports granting access to the interior volume. Sound dampening materials cover at least part of the interior volume. At least one speaker located within the interior volume. At least one microphone located within the interior volume.

Another object of the electronic device tester is to have a boarder placed around an opening perimeter of the door.

Another object of the electronic device tester is to have a plurality of wire connections located within the interior volume. The wire connections provide access to the exterior of the housing.

Another object of the electronic device tester is to have a bracket within the interior volume.

Another object of the electronic device tester is to have the bracket is secured to at least one slider.

Another object of the electronic device tester is to have the bracket is configured to secure an electronic device.

Another object of the electronic device tester is to have the configuration include at least one fitting.

Another object of the electronic device tester is to have a fitting comprised of at least one removable end cap.

Another object of the electronic device tester is to have a screen secured to the housing and operably coupled to a computer.

Another object of the electronic device tester is to have the screen is configured to display a graphical user interface.

Other objects, features and advantages of the present invention will become apparent from the following detailed description taken in conjunction with the accompanying drawings.

### BRIEF DESCRIPTION OF THE DRAWINGS

The accompanying drawings are incorporated in and are to be considered part of the present specification. These drawings are meant to aid the reader's understanding and comprehension of the present disclosure and are depictions of various example embodiments. The drawings are not to be considered limiting upon the disclosure. It should specifically be noted that the drawings are examples and may not necessarily be drawn to scale.

FIG. 1 shows a block diagram of a computing system.

FIG. 2A shows a front view of an example of a mobile phone device.

FIG. 2B shows a rear view of an example of a mobile phone device.

FIG. 3 shows a perspective view of an embodiment of the housing of the electronic device tester.

FIG. 4 shows a perspective view of an embodiment of the test chamber of the electronic device tester.

FIG. 5 shows a close-up view of an embodiment of the screen of the electronic device tester.

FIG. 6 shows a flow chart of an embodiment of the method for testing electronic devices using the electronic device tester.

### DETAILED DESCRIPTION OF THE INVENTION

For the purposes of presenting a brief and clear description of the present invention, a preferred embodiment will be discussed as used for the electronic device tester. The figures are intended for representative purposes only and should not be considered to be limiting in any respect.

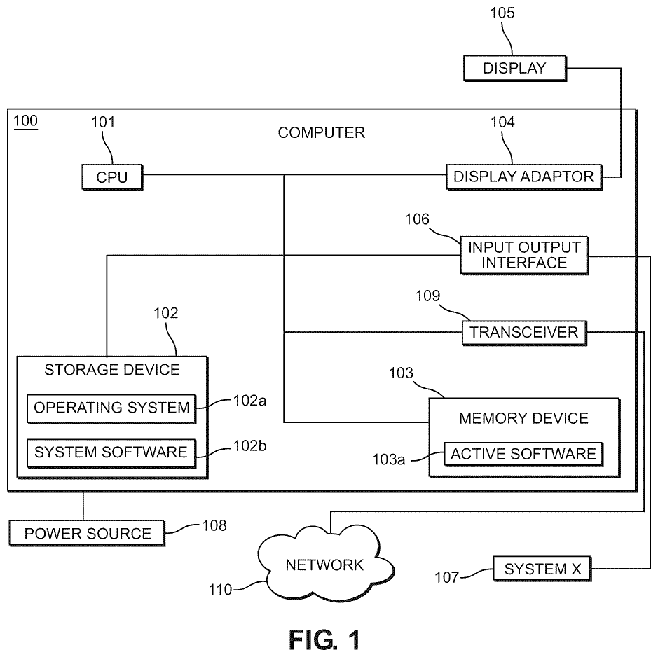

Referring now to FIG. 1, there is shown a block diagram of a computing system. Computing systems may have many interchangeable parts or multiples of some parts. One of ordinary skill in the art will understand that the shown computer 100 is a basic computing system demonstrating a minimal amount of parts to allow for the computer to function. Computer 100 is exemplary, and one of ordinary skill in the art will recognize that computer 100 may be altered as necessary to render the presently disclosed system operable or to provide a peak performance of the disclosed system.

The parts described are each operably coupled together as necessary, one of ordinary skill in the art will understand how to connect general computer components, for example by use of a motherboard or other computer board. In the shown embodiment the computer 100 includes a CPU 101. In one embodiment the CPU 101 includes only one processor. In other embodiments the CPU 101 may be made up of multiple processors. Different processors will allow for different computing power and speed.

The computer 100 includes at least one storage device 102. In different embodiments the at least one storage device 102 may be a solid-state storage device, a disk storage device, or another suitable storage device. One of ordinary skill in the art will recognize that there are several types of computing storage devices each providing well-known benefits and drawbacks. The at least one storage device 102 will store at least the computer operating system 102a and system software 102b. System software 102b may include any software necessary, or optionally, used to run any system described herein.

The computer 100 will have at least one memory device 103. One of ordinary skill in the art will recognize that there are several types of computing memory devices each providing well known benefits and drawbacks. The at least one memory device 103 will store at any active software 103a. Active software 103a may include the operating system 102a or parts of the system software 102b. The at least one memory device 103 may store the entire system software 102b size and speed permitting.

The computer 100 may also include various connection ports and types. The computer 100 may have a display adaptor 104. The display adaptor 104 will allow the computer 100 to connect to at least one display 105. In other embodiments multiple displays may be connected to the display adaptor 104. Similarly, the computer 100 may include at least one input/output interface 106. The input/output interface 106 will allow the computer 100 to connect to at least one system, referred to as System X 107 in FIG. 1. The input/output interface 106 may also allow for connection to only part of System X 107 or multiple systems. The computer 100 will also be operably connected to a required power source 108.

The computer 100 may also include a transceiver 109. In one embodiment the transceiver 109 is a wired transceiver. In another embodiment the transceiver 109 is a wireless transceiver. The transceiver 109 will allow the computer 100 to connect to a network 110. The network 110 may be an internet or an intranet connection. The network 110 will allow for the computer 100 to potentially connect to multiple other computing devices. In another embodiment the network may allow for the computer 100 to connect to multiple systems. In one embodiment the computer 100 will allow for System X 107 to be connected to the network 110.

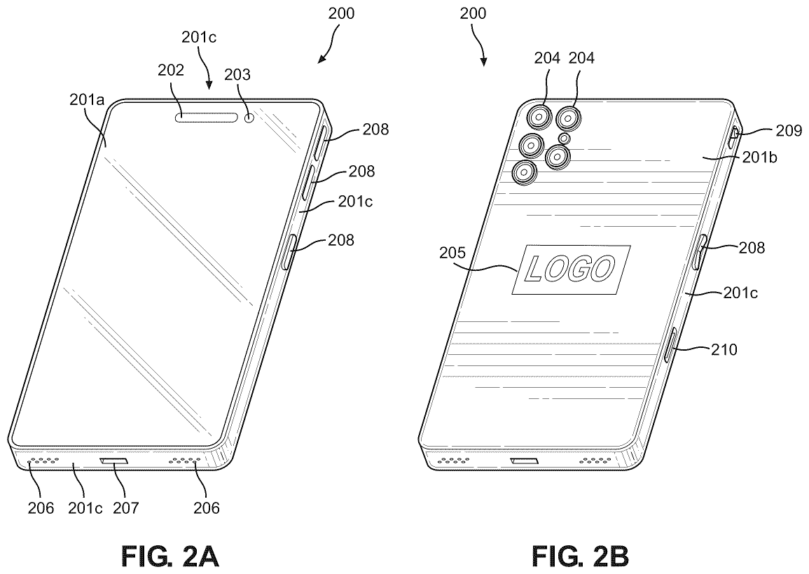

Referring now to FIG. 2A and FIG. 2B, there is shown a front view and a rear view of an example of an electronic device 200, such as a mobile phone device. Electronic devices may have many different parts and components. Even like parts or components may be in various locations or have different shapes and sizes. One of ordinary skill in the art will understand that the shown electronic device 200 is merely an example of the exterior of a device. Any specialized or specific features or requirements of devices will be detailed herein as necessary. However, one of ordinary skill in the art will understand that many electronic devices 200 have many of these described characteristics. Further, electronic devices, such as mobile phone devices, operate on a computer-based platform having many of the computer parts as described in FIG. 1. The below description seeks to detail external components and not the computer which runs the electronic device 200. The electronic device 200 can be, without limitation, a mobile phone device, or a tablet. In one embodiment other electronic devices may be used such as laptops, cable set top boxes, routers, or antennas.

The shown electronic device 200 includes a front surface 201a, a rear surface 201b, and four side surfaces 201c. The front surface 201a typically includes a screen which covers a majority of the surface. The screen is typically covered with a specialized material, currently a glass product. The front surface 201a may also include a speaker opening 202 and a camera opening 203.

The rear surface 201b of the electronic device 200 may include at least one camera lens 204. In the shown embodiment there are a plurality of camera lenses 204. In another embodiment at least one light lens is secured to the rear surface 201b. In many embodiments the rear surface 201b includes a logo 205. The logo 205 may represent the company which created the electronic device 200. The rear surface 201b may include a coating or covering to decorate or protect the rear surface. For example, a coating may be applied to the rear surface 201b to ensure a shiny surface.

The side surfaces 201c of the electronic device 200 may include any or all of the following parts. In one embodiment the electronic device 200 will have several openings for speaker output 206. The electronic device 200 will also include a charging port 207. Charging ports 207 may include a prong therein to secure to a charging cord. An electronic device 200 may include a plurality of buttons 208 along the side surfaces 201c. In different embodiments the plurality of buttons 208 may allow for volume control, locking the electronic device 200, or other desired functions. In some embodiments the electronic device 200 may include a switch 209. In yet another embodiment the electronic device 200 includes a SIM card slot or other card slot 210.

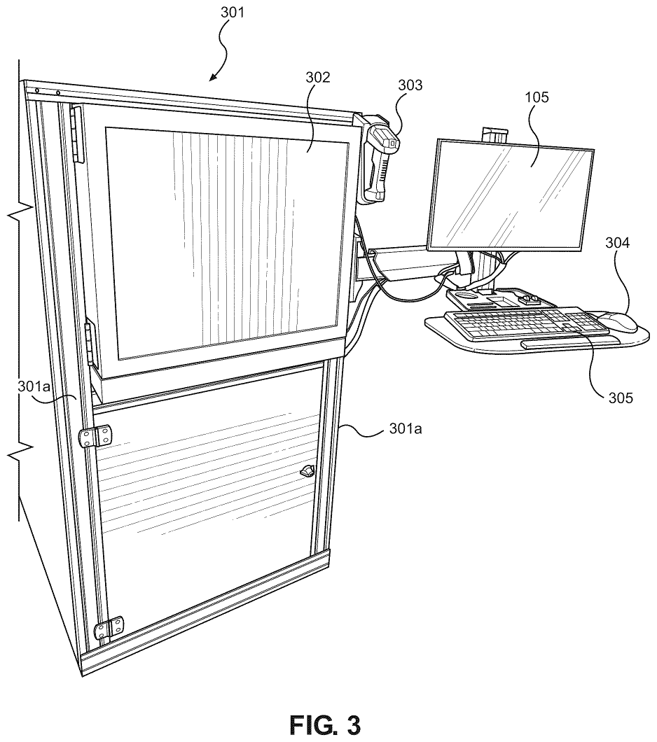

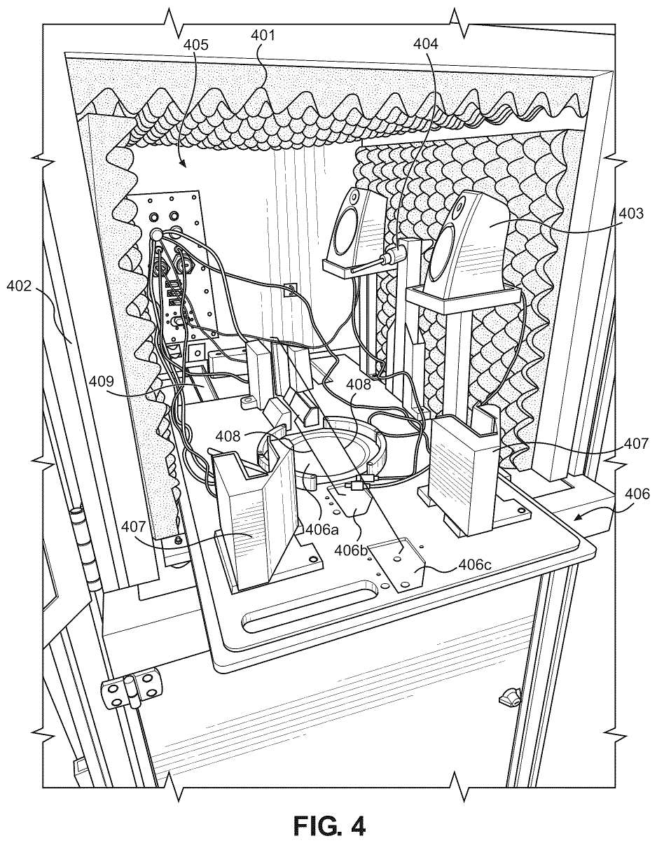

Referring now to FIG. 3, there is shown a perspective view of an embodiment of the housing of the electronic device tester. The electronic device tester is comprised of a housing 301. The housing 301 has a plurality of supports 301a. The plurality of supports 301a support a door 302. The door 302 opens and closes a test chamber as described in FIG. 4.

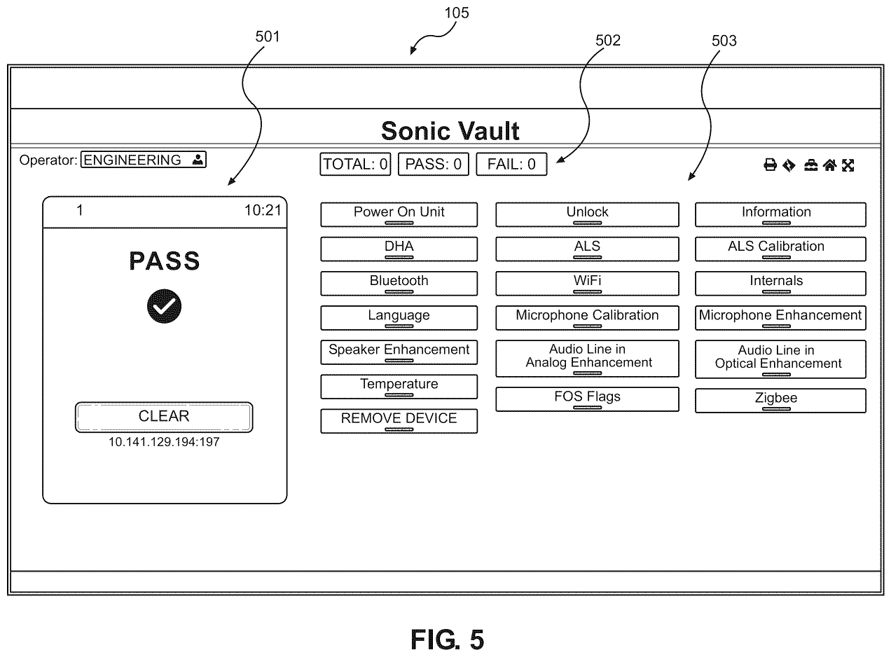

In the shown embodiment a scanner 303 is secured to the plurality of supports 301a. The scanner 303 is operably coupled to the computer as described in FIG. 1. The scanner is capable of scanning bar codes so that that testing system as described in FIG. 5 can retrieve device information.

In the shown embodiment the screen 105 is also secured to the plurality of supports 301a. In some embodiment the screen 105 may be a human machine interface. This will eliminate the need for a mouse 304, keyboard 305, or other forms of input devices. In the shown embodiment a mouse 304 and a keyboard 305 are included. These components are both operably secured to the computer as a way to control the testing system.

Referring now to FIG. 4, there is shown a perspective view of an embodiment of the test chamber of the electronic device tester. The test chamber includes a sound dampening material 401. The sound dampening material 401 keeps exterior noise out of the test chamber during testing. The sound dampening material 401 can also be used to prevent noise from exiting the test chamber during testing. In one embodiment a boarder 402 is also placed around the chamber door opening. This boarder 402 will allow for sound dampening. In another embodiment the boarder 402 will prevent light from entering or exiting the test chamber.

The test chamber includes at least one speaker 403. The at least one speaker 403 is operably coupled to the computer. During testing the speakers can play desired sounds. In addition to the at least one speaker 403 at least one microphone 404 is also included in the test chamber. The at least one microphone 404 is operably coupled to the computer. The microphone 404 will allow the test system to record sound played from a device being tested.

The test chamber includes a plurality of wire connections 405. These wire connections 405 will enable each of the test components to be operably coupled to the computer. The wire connections 405 will allow for connections to be made all while keeping the chamber sealed. In some embodiments the wire connections 405 allow for additional connection slots. The extra slots allow for the tester to be customized to meet the needs of the user.

The test chamber is comprised of at least one bracket 406 which will secure the device to be tested in place. In the shown embodiment the bracket 406 has 3 securement sections 406a, 406b, and 406c. This multitude of securement sections 406a, 406b, and 406c allows for several different devices to be installed in the test chamber for testing without changing or modifying the bracket 406. In the current embodiment, there are removable end caps 407, which can be moved and placed in the fittings 408 to create the different securement sections 406b, 406c.

Further, in the shown embodiment the bracket 406 is secured to sliders 409. The sliders 409 will allow for the bracket to be slide out of the test chamber. This will allow for larger devices to be placed in the bracket 406 without having the test chamber walls interfere. In use the bracket 406 can be slid from the test chamber via the sliders 409, a device can be placed in the bracket 406 or removed from the bracket 406 and the bracket 406 can be slid back into the test chamber.

Referring now to FIG. 5, there is shown a close-up view of an embodiment of the screen of the electronic device tester. The screen 105 for the electronic device tester is configured to display a graphical user interface (GUI). The shown embodiment is merely an example of items the GUI may show however, it is not meant to be limiting on the present invention. Any number of items may be shown on the screen as a user may find useful.

In the shown embodiment the GUI shows a pass/fail section 501 for the device being tested. This will let the user know if the tested device has passed each test of failed the procedure. The GUI further shows a tabulation section 502. This section can show the total number of units tested, the total number of units passed, and the number of units which failed the test procedure. In the shown embodiment the GUI shows every test 503 which is run on a device. The test section 503 can show whether a device passes or fails any specific test. This can help a user know if a device should be retested, fixed, or scrapped. In one embodiment system life time metrics can be displayed on the GUI such as failure rates over time or a correlation of types of failures.

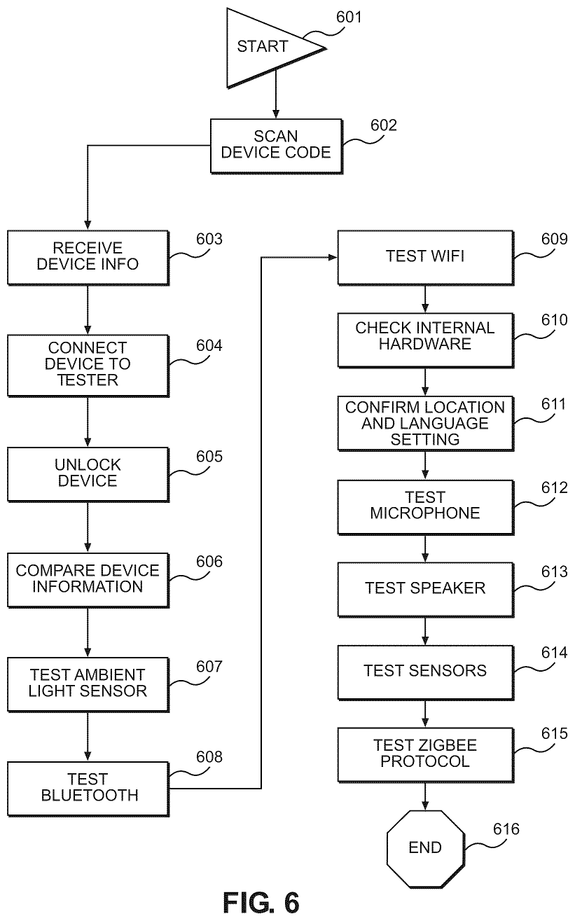

Referring now to FIG. 6, there is shown a flow chart of an embodiment of the method for testing electronic devices using the electronic device tester. In one embodiment the method for testing an electronic device using the electronic device tester starts 601 by scanning the electronic device to be tested 602. At the time of filing this application many devices have bar codes printed on them to capture the device model and serial number. In other instances, custom codes may be applied to the electronic device by the user. Afte the code is scanned 602, device information is received 603. The device information can be retrieved from a network which the electronic device tester is connected to.

Next the electronic device is connected to the electronic device tester 604. Once connected the electronic device tester sends a signal to the electronic device to unlock the electronic device 605 which allows for further communications. Once unlocked the information retrieved by scanning the device in step 602 is compared to information stored on the electronic device 606. This ensures that the proper device is being tested. Further, this check can be used to ensure that the device and the tester are properly speaking to one another.

In the shown embodiment, if the electronic device has ambient light sensors then the ambient light sensors are tested 607. As described above, the chamber is configured to keep the chamber in complete darkness so there is no ambient light. Therefore, the sensors will read zero. If the sensors do not read zero, then the ambient light sensors will be recalibrated such that they read zero.

Next the Bluetooth® is tested 607. The electronic device tester sends a signal to the electronic device to search for Bluetooth® signals. If a signal is found the name of the signal is compared to an expected signal name to ensure. As long as any of the received Bluetooth® signal(s) matches the expects results then the electronic device passes the test. The WiFi is then tested 609. The WiFi test is conducted in a similar manner. The electronic device is directed to search for WiFi signals. The name of the signals are then compared to an expected name. As long as any one of the received WiFi signals matches the expected signal then the electronic device passes the test.

After the WiFi test 609 then the internal hardware is checked 610. In order to perform this check signals are sent to various components. If the component responds than the test is passed. A software check is performed to confirm that the device is programmed for the correct world location and languages 611. For example devices build for United States may come back as set for the United States having a primary language of English and options for French, Spanish, or any other optional languages. If a device which is supposed to be used in the United States comes back as a device for Australia the device would fail the test.

Next the electronic devices microphone is tested 612. In one embodiment the microphone is tested by conducting a frequency sweep. In one embodiment multiple different frequencies are played one at a time for 500 ms each from the test chamber speaker while simultaneously the electronic device is set to record from its microphone(s). The recording files created by the electronic device are pulled onto the test PC and then analyzed by the test software. A set of sub-tests is performed to evaluate the electronic device's microphones using these recording files.

In some embodiments sub-tests are run. In one embodiment sub-test 1 is a frequency response. In one embodiment this test is conducted by checking the recorded signal at a series of frequencies and compared to an upper and lower limit. The sub-test will fail if any amplitudes are outside the limits. The limits are set in terms of Decibels. Each device to be tested will have different necessary limits. However, in one embodiment Decibels limits can be inversely compiled and a limit can be between −70 and −10. In another embodiment the Decibels limit can be between −100 and 0. These limits are for example purposes and, again, each device will require its own set of limits as dictated by the device. One of ordinary skill in the art will be able to determine these limits without undue experimentation.

In some embodiments sub-test 2 is a total harmonic distortion (THD) test. In one embodiment this test is conducted by recording is repeated with a series of tones. Each tone's recording is converted into the frequency domain and used to calculate the THD for the frequency associated with that step. The sub-test will fail if any THD values are above the threshold. THD will be measured with 5 harmonics into consideration. This means for THD measurement at 1 kHz, the RMS values at 2 kHz, 3 kHz, 4 kHz and 5 kHz are considered.

After the microphone(s) are tested the electronic device's speaker(s) are tested. In one embodiment the speakers are tested in the same manner as the microphone but the device plays the sounds and the electronic device tester records them. In some embodiments an additional sub-test is conducted.

In some embodiments a rub and buzz test of the speaker may be conducted. In this test the system is looking for a potentially blown speaker or a particle of debris located on the speaking causing an abnormal sound. In this embodiment a THD is calculated for the chosen speaker. Then a Higher Order Harmonic Distortion is chosen. This will look for only output outside of the expect Hertz range. If such an output is detected it signals an issue with the speak from damage or debris.

In some embodiments where a device has multiple input connections the speaker test is conducted twice. This will allow for each the audio line in for analog via a standard 3.5 mm audio jack to be tested as well as an optical audio line or HDMI audio line. This allows for additional hardware to be tested along with the speakers.

Once the microphone(s) are tested 612 and the speaker(s) are tested 613 other device sensors are tested 614. In one embodiment a temperature sensor is tested. In one embodiment the system can compare the expected temperature to a reading from the temperature sensor in which case only a matching reading will pass. In another embodiment any response from the temperature sensor will constitute a passed test. Another sensor test may include retrieving the devices expected life cycle results. In one embodiment any response may constitute a passed test.

Another test which may be preformed is a testing of the Zigbee protocol 615. The Zigbee protocol is used in all manner of IOT products. In order to test this protocol the signal quality, range and network connectivity are evaluated against known values. In one embodiment the Zigbee standard is also evaluated compared to known and expected values. After such time the method ends 616. In different embodiments steps may be left out or the order changed. It is contemplated by this disclosure that different tests may be needed or a different order may be used to accomplish a user's goals. The electronic device tester is designed and build to accommodate various users needs.

It is therefore submitted that the methods, systems, and devices have been shown and described in what is considered the most practical and preferred embodiments along with specific examples. It is recognized, however, that departures may be made within the scope and these present examples are not intended to be limiting. One of ordinary skill the art will be able to discern that obvious modifications can be made without departing from the scope or spirit.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention. Similarly, it is to be realized that, it is not intended for any method set forth herein to be construed as requiring that its steps be performed in a specific order, unless otherwise set forth in the claims.

Therefore, the foregoing is considered as illustrative only of the principles of the disclosure. Further, since numerous modifications and changes will readily occur to those skilled in the art, it is not desired to limit the invention to the exact construction and operation shown and described, and accordingly, all suitable modifications and equivalents may be resorted to, are deemed to fall within.

What is claimed:

1. An electronic device tester, comprising:
a housing created by a plurality of supports, wherein the housing has an interior volume;
a door secured to the plurality of supports granting access to the interior volume;
sound dampening materials covering at least part of the interior volume;
at least one speaker located within the interior volume;
at least one microphone located within the interior volume.

2. The electronic device tester of claim 1, further comprising a boarder placed around an opening perimeter of the door.

3. The electronic device tester of claim 1, further comprising a plurality of wire connections located within the interior volume, where in the wire connections provide access to the exterior of the housing.

4. The electronic device tester of claim 1, further comprising a bracket within the interior volume.

5. The electronic device tester of claim 4, wherein the bracket is secured to at least one slider.

6. The electronic device tester of claim 4, wherein the bracket is configured to secure an electronic device.

7. The electronic device tester of claim 6, where the configuration includes at least one fitting.

8. The electronic device tester of claim 7, wherein a fitting is comprised of at least one removable end cap.

9. The electronic device tester of claim 1, further comprising a screen secured to the housing and operably coupled to a computer.

10. The electronic device tester of claim 9, wherein the screen is configured to display a graphical user interface.
